(19) United States
(12) Patent Application Publication
(10) Pub. No.: US 2026/0092196 A1
(43) Pub. Date: Apr. 2, 2026

(54) CMP COMPOSITION INCLUDING CERIA POLYMER COMPOSITE PARTICLES

(71) Applicant: ENTEGRIS, INC., Billerica, MA (US)

(72) Inventors: Steven Grumbine, Aurora, IL (US); William J. Ward, Aurora, IL (US); Qiang Zhao, Woodridge, IL (US)

(21) Appl. No.: 19/327,610

(22) Filed: Sep. 12, 2025

Related U.S. Application Data
(60) Provisional application No. 63/699,933, filed on Sep. 27, 2024.

(51) Int. Cl. C09G 1/02; B24B 37/04; C08G 83/00; C09K 3/14; H01L 21/3105

(52) U.S. Cl. CPC C09G 1/02; B24B 37/044; C08G 83/001; C09K 3/1436; H10P 95/062

(57) ABSTRACT

A chemical mechanical polishing composition comprises, consists of, or consists essentially of a liquid carrier and ceria polymer composite particles dispersed in the liquid carrier. The ceria polymer composite particles comprise, consist of, or consist essentially of ceria particles covalently bonded to and at least partially embedded in a polymer matrix.

### BACKGROUND OF THE INVENTION

Chemical mechanical polishing (CMP) compositions and methods for polishing (or planarizing) the surface of a substrate are well known. Polishing compositions (also known as polishing slurries, CMP slurries, and CMP compositions) for dielectric layers (such as silicon oxide) on a semiconductor substrate may include abrasive particles suspended in an aqueous solution and various chemical additives such as polishing rate accelerators, topography control agents, buffers, and the like.

In a conventional CMP operation, the substrate (wafer) to be polished is mounted on a carrier which is in turn mounted on a carrier assembly and positioned in contact with a polishing pad in a CMP polishing tool. The carrier assembly provides a controlled pressure to the substrate against the polishing pad. The substrate and pad are moved relative to one another by an external driving force. The relative motion of the substrate and pad abrades and removes a portion of the material from the surface of the substrate, thereby polishing the substrate. The polishing of the substrate by the relative movement of the pad and the substrate may be further aided by the chemical activity of the polishing composition and/or the mechanical activity of an abrasive suspended in the polishing composition.

In many CMP operations achieving optimum removal rates and minimal defects is desired. For example, in advanced dielectric CMP operations high removal rates are desired to maintain throughput and low defect counts are desired to maintain a high yield. However, achieving high removal rates and low defect counts can be challenging. For example, ceria abrasive compounds are commonly used to achieve high removal rates but can also be prone to imparting surface defects. Despite many advances to commercial CMP compositions, there remains a need in the industry for CMP compositions that provide high dielectric removal rates and reduced defects during a CMP operation.

### BRIEF SUMMARY OF THE INVENTION

A chemical mechanical polishing composition is disclosed. The composition comprises, consists of, or consists essentially of a liquid carrier and ceria polymer composite particles dispersed in the liquid carrier. The ceria polymer composite particles comprise, consist of, or consist essentially of ceria particles covalently bonded to and at least partially embedded in a polymer matrix.

### BRIEF DESCRIPTION OF THE DRAWINGS

For a more complete understanding of the disclosed subject matter, and advantages thereof, reference is now made to the following descriptions taken in conjunction with the accompanying drawings, in which:

FIGS. 1A and 1B (collectively FIG. 1) depict scanning electron microscopy (SEM) images of example embodiments of the ceria polymer composite particles disclosed herein.

FIG. 2 depicts an SEM image obtained using focused ion beam scanning electron microscopy (FIB-SEM) tomography on an example embodiment of the ceria polymer composite particles disclosed herein.

FIGS. 3A and 3B (collectively FIG. 3) depict SEM images of other example embodiments of the ceria polymer composite particles disclosed herein.

### DETAILED DESCRIPTION OF THE INVENTION

Chemical mechanical polishing compositions and methods for using those compositions to polish a substrate are disclosed. In one example embodiment, a chemical mechanical polishing composition comprises, consists essentially of, or consists of a liquid carrier and ceria polymer composite particles dispersed in the liquid carrier. The ceria polymer composite particles comprise, consist of, or consist essentially of ceria particles covalently bonded to and at least partially embedded in a polymer matrix. In optional embodiments, the polishing composition may further include an aminosilane compound that is covalently bonded with an outer surface of the ceria polymer composite particles such that the ceria polymer composite particles have a positive charge in the polishing composition.

A method for formulating a chemical mechanical polishing composition includes preparing an emulsion of negatively charged ceria particles and a silane monomer and polymerizing the emulsion to obtain the dispersion of ceria polymer composite particles. The ceria polymer composite particles include ceria particles covalently bonded to and at least partially embedded in a polymer matrix. In example embodiments, the method may further optionally include covalently bonding an aminosilane compound to the ceria polymer composite particles to obtain a dispersion of positively charged ceria polymer composite particles.

A method for polishing a dielectric containing substrate includes contacting the substrate with the polishing composition, moving the polishing composition relative to the substrate, and abrading the substrate to remove a portion of at least one dielectric layer from the substrate and thereby polish the substrate.

The polishing composition contains ceria polymer composite particles in (e.g., dispersed in) a liquid carrier. As used herein the term ceria polymer composite particles refers to individual particles that contain a plurality of discrete ceria particles in (e.g., embedded in) a polymeric matrix. The disclosed ceria polymer composite particles may be referred to herein in shorthand as composite particles. The disclosed ceria polymer composite particles may optionally be modified or treated with an aminosilane compound such that they have a permanent positive charge (e.g., have a positive zeta potential) in the polishing composition (e.g., at point of use).

The disclosed ceria polymer composite particles include a plurality of ceria particles that are covalently bonded to and at least partially embedded in a polymer matrix. The ceria particles may be partially embedded such that a portion of individual ceria particles protrude outward from the polymer matrix at the surface of the composite particle (such that a first portion of the ceria particle is embedded and a second portion of the ceria particle protrudes) and/or fully embedded (enclosed) in the polymer (i.e., in the interior of the composite particle). While the disclosed embodiments are not limited in this regard, it is believed that the best polishing results are obtained when a portion of at least some of the individual ceria particles protrude outward from the polymer matrix. In this way, the protruding portion of the ceria particles may interact directly with the polished substrate.

The disclosed ceria polymer composite particles may contain substantially any suitable ceria particles, for example, including wet process ceria, precipitated ceria, fumed ceria, sintered (calcined) ceria, and/or condensation polymerized ceria particles. By ceria particles it is meant particles that are primarily or mostly ceria. Suitable ceria particles may also include doped ceria particles or ceria particles including small amounts (such as a few percent) of other elements or compounds, such as other oxides. Ceria particles suitable for polishing substrates are well known in the CMP industry and are commercially available.

The ceria particles are generally small since they are at least partially embedded in the polymer matrix. By small it is meant that the ceria particles have an average particle size of less than about 100 nm (as described in more detail below). It will be appreciated that the particle size of discrete particles, such as a particle suspended in a liquid carrier, may be defined in the industry using various particle size measurement methods. For example, the particle size may be defined as an equivalent circle diameter (ECD) particle size that may be measured using electron microscopy images, such as transmission electron microscopy (TEM) or secondary electron scanning electron microscopy (SEM) images, or measured by dynamic light scattering. The discrete ceria particles embedded in the ceria composite particles may have an average ECD particle size of about 1 nm or more (e.g., about 2 nm or more, about 3 nm or more, or about 5 nm or more). The ceria particles may have an average ECD particle size of about 50 nm or less (e.g., about 40 nm or less, about 30 nm or less, or about 20 nm or less). Accordingly, the ceria particles may have an average ECD particle size in a range bounded by any two of the aforementioned endpoints, for example, from about 1 nm to about 50 nm (e.g., from about 2 nm to about 40 nm, from about 3 nm to about 30 nm, or from about 5 nm to about 20 nm).

It will be appreciated that the measured particle size of a particle (such as a ceria particle), for example, suspended in a liquid carrier, commonly depends on the measurement technique and that the particle size measured using a dynamic light scattering technique is commonly greater than the ECD particle size measured using TEM or SEM images (particularly for small particles). As such, when the ceria particles are measured prior to forming the composite particles using dynamic light scattering, such as with a Malvern Zetasizer®, the discrete ceria particles may have an average particle size of about 1 nm or more (e.g., about 5 nm or more, about 10 nm or more, or about 20 nm or more). The ceria particles may have an average particle size of about 100 nm or less (e.g., about 80 nm or less, about 60 nm or less, or about 50 nm or less). Accordingly, the ceria particles may have an average particle size in a range bounded by any two of the aforementioned endpoints, for example, from about 1 nm to about 100 nm (e.g., from about 5 nm to about 80 nm, from about 10 nm to about 60 nm, or from about 20 nm to about 50 nm).

The ceria particles may optionally also (or alternatively) be characterized as having a Brunauer-Emmett-Teller (BET) surface area of greater than about 15 m²/g (e.g., greater than about 20 m²/g, greater than about 25 m²/g, greater than about 30 m²/g, greater than about 35 m²/g, or greater than about 40 m²/g). The BET surface area may further be less than about 300 m²/g (e.g., less than about 280 m²/g, less than about 250 m²/g, less than about 220 m²/g, less than about 200 m²/g, or less than about 180 m²/g). Accordingly, the ceria particles may have a BET surface area in a range bounded by any two of the aforementioned endpoints, for example, from about 20 m²/g to about 300 m²/g (e.g., from about 25 m²/g to about 250 m²/g, from about 30 m²/g to about 200 m²/g, or from about 40 m²/g to about 180 m²/g).

The composite particles may advantageously have a high purity. For example, the composite particles may have a total metals impurity (in which the metals include sodium, aluminum, calcium, magnesium, and the transition metals) of less than about 20 parts per million (ppm) on a weight basis (e.g., less than about 15 ppm, less than about 10 ppm, less than about 5 ppm, less than about 2.5 ppm, or less than about 1 ppm). In such embodiments, the composite particles may be potassium or ammonia stabilized. The composite particles may further have a total metals impurity (in which the metals include potassium, sodium, iron, aluminum, calcium, magnesium, titanium, nickel, chromium, copper, and zinc) of less than 20 parts per million (e.g., less than 15 ppm, less than 10 ppm, less than 5 ppm, less than 2.5 ppm, or less than 1 ppm). In such embodiments, the composite particles may be ammonia or amine stabilized.

In the disclosed embodiments, the ceria polymer composite particles include ceria particles that are covalently bonded to and at least partially embedded in a polymer matrix. It has been found that composite particles including covalently bonded ceria particles may provide one or more advantages. While not wishing to be bound by theory, it is believed that the strong covalent bonds between the ceria particles and the polymer matrix result in composite particles having high mechanical integrity (such that the discrete ceria particles are unlikely to separate from the polymer either during slurry mixing or during a polishing operation). As such, the disclosed compositions tend to have few (if any) discrete ceria particles dispersed therein. The disclosed compositions are therefore expected to provide consistently high removal rates, low defectivity, and good cleanability. Moreover, the disclosed compositions are expected to be more readily treated in a waste stream than compositions that include fine ceria particles.

The polymer matrix may include substantially any suitable polymeric material. For example, the polymer matrix may include polymers having styrene, acrylate and methacrylate, olefin, vinyl ester, and/or acrylonitrile monomers as well as other monomers that may be polymerized by radical polymerization. The polymer matrix may include a homopolymer or a copolymer. In certain advantageous embodiments, the polymer matrix may include a silicon containing monomer, such as silicon containing substituted and/or unsubstituted vinyl, acrylate, and/or methacrylate monomers, such that the ceria polymer composite particles may contain Ce—O—Si covalent bonds. In preferred embodiments, the polymer matrix includes acrylamide, acrylate, or methacrylate monomers, for example, including the most preferred 3-trialkoxysilylpropyl methacrylate monomer (e.g., 3-trimethoxysilylpropyl methacrylate), 2-(trimethylsilyloxy)ethyl methacrylate, 3-(trialkoxysilyl)propyl acrylate. It will, of course, be understood that the monomers are precursors that may undergo hydrolysis and condensation during synthesis.

The ceria polymer composite particles may be polymerized, for example, using known emulsion polymerization techniques in which an initiator is added to a blended mixture of an aqueous dispersion of ceria particles and the monomer (e.g., a methacrylate monomer of the most preferred 3-trialkoxysilylpropyl methacrylate monomer). Preferred monomers include a polymerizable group on one end and a silicon containing group on another end (e.g., a methacrylate group on one end and a trialkoxysilyl group on the other end such that the monomer bonds with the Ce—OH groups on the ceria particles to form a covalent bonds such as Ce—O—Si covalent bonds). One example polymerization procedure is described in more detail below in Example 1.

In certain example embodiments, the ceria composite particles may be anionic (i.e., negatively charged) in the polishing composition. In such embodiments, the anionic ceria composite particles may have a zeta potential calculated with a Smoluchowski approximation (referred to herein as a Smoluchowski zeta potential) in the polishing composition of less than about negative −10 mV (e.g., less than about −20 mV, less than about −25 mV, less than about −30 mV, less than about −35 mV, or less than about −40 mV). In such anionic embodiments, the pH of the polishing composition is preferably greater than about 6 (e.g., greater than about 7).

In example embodiments, the negative charge may be the result of the synthesis procedure. For example, the composite particles may be synthesized from a high pH emulsion of negatively charged ceria particles such that the composite particles have a negative charge. In such embodiments, the negatively charged ceria particles may be obtained, for example, via admixing the ceria particles with a carboxylate such as citrate.

While the disclosed embodiments are not limited in this regard, the negative charge (negative zeta potential) of the composite particles may be enhanced, for example, via covalently bonding a negatively charged compound (e.g., a silicon containing compound having an anionic group) to the surface of the composite particles. In such embodiments, the anionic group may advantageously include an organic acid group such as a carboxylic acid, a sulfonic acid, and/or a phosphonic acid (e.g., including a carboxylate group, a sulfonate group, and/or a phosphonate group). Suitable compounds including a carboxylate group or carboxylate precursor may include, for example, (3-triethoxysilyl) propylsuccinic anhydride, carboxyethylsilane triol or salts thereof, and N-(trialkoxysilylpropyl)ethylenediaminetriacetic acid or salts thereof. A carboxylate precursor is converted (e.g., oxidized) to or converts in situ (e.g., during work-up) to a carboxylate group. Suitable compounds including a phosphonate group may include, for example, 3-(trihydroxysilyl) propyl methylphosphonic acids and salts thereof.

In some embodiments, the silicon containing compound includes a negatively-charged sulfonate group (or sulfonic acid group). The compound may include one or more sulfonate groups or sulfate groups. The sulfonate group may also be a sulfonate or sulfate precursor, which can subsequently be transformed into sulfonate or sulfate, for example, by oxidation. Suitable sulfonate groups include, for example, 3-(trihydroxysilyl)-1-propanesulfonic acid, tricthoxysilylpropyl(polyethyleneoxy) propylsulfonic acid salts thereof such as potassium salts. Suitable sulfonate precursors include, for example, 3-mercaptopropyltrialkoxysilane, (mercaptomethyl)methyldicthoxysilane, and 3-mercaptopropyulmethyldialkoxysilane.

In certain other example embodiments, the ceria composite particles may be cationic (i.e., positively charged) in the polishing composition. For example, the cationic ceria composite particles may have a Smoluchowski zeta potential in the polishing composition of greater than about 10 mV (e.g., greater than about 20 mV, greater than about 25 mV, greater than about 30 mV, greater than about 35 mV, or greater than about 40 mV). Moreover, in such cationic embodiments, the pH of the polishing composition is preferably greater than about 2 (e.g., greater than about 3) and less than about 6 (e.g., less than about 5.5 or less than about 5).

The positive charge on the ceria polymer composite particles may be obtained by covalently bonding the composite particles with a nitrogen containing compound, such as an aminosilane compound. In example embodiments, the aminosilane compound may include primary aminosilanes, secondary aminosilanes, tertiary aminosilanes, quaternary aminosilanes, and/or a multi-podal (e.g., dipodal) aminosilane. In advantageous embodiments, the aminosilane compound may include, for example, a propyl group containing aminosilane, or an aminosilane compound including a propyl amine. Examples of suitable classes of aminosilanes may include bis(2-hydroxyalkyl)-3-aminoalkyl trialkoxysilane, dialkylaminoalkyltrialkoxysilane (e.g., dialkylaminoalkoxysilane), (N,N-dialkyl-3-aminoalkyl)trialkoxysilane), trialkoxysilane, 3-(N-styrylalkyl-2-aminoalkylaminoalkyl trialkoxysilane), aminoalkyl trialkoxysilane, (2-N-benzylaminoalkyl)-3-aminoalkyl trialkoxysilyl alkyl-N,N,N-trialkyl ammonium, N-(trialkoxysilylalkyl)benzyl-N,N,N-trialkyl ammonium, (bis(alkyldialkoxysilylalkyl)-N-alkhyl amine, bis(trialkoxysilylalkyl) urea, bis(3-(trialkoxysilyl)alkyl)-ethylenediamine, bis(trialkoxysilylalkyl)amine, bis(trialkoxysilylalkyl)amine, 3-aminoalkyltrialkoxysilane, N-(2-aminoalkyl)-3-aminopropylmethyldialkoxysilane, N-(2-aminoalkyl)-3-aminoalkyltrialkoxysilane, 3-aminoalkylmethyldialkoxysilane, 3-aminoalkyltrialkoxysilane, (N-trialkoxysilylalkyl) polyethyleneimine, trialkoxysilylalkyldiethylenetriamine, N-phenyl-3-aminoalkyltrialkoxysilane, N-(vinylbenzyl)-2-aminoalkyl-3-aminoalkyltrialkoxysilane, 4-aminoalkyltrialkoxysilane, and mixtures thereof.

In other advantageous embodiments, the ceria polymer composite particles may be covalently bonded with a multi-podal (e.g., dipodal) aminosilane, such bis(trialkoxysilyl)ethane, bis(trialkoxysilylalkyl)amine (e.g., bis(trialkoxysilylalkyl)amine or bis(trialkoxysilylpropyl)amine), N-(hydroxyalkyl)-N,N-bis(trialkoxysilylalkyl)amine, N,N′-bis[(3-trialkoxysilyl)alkyl]ethylenediamine, N,N′-bis(2-hydroxyalkyl)-N,N′-bis(trialkoxysilylalkyl)ethylenediamine, tris(trialkoxysilylalkyl)amine, 1,11-bis(trialkoxysilyl)-4-oxa-8-azaundecan-6-ol, and mixtures thereof. Those of ordinary skill in the art will readily appreciate that aminosilane compounds are commonly hydrolyzed (or partially hydrolyzed) in an aqueous medium. Thus, by reciting an aminosilane compound, it will be understood that the modifying aminosilane may include a hydrolyzed (or partially hydrolyzed) species and/or condensed species thereof.

In example embodiments including a covalently bonded aminosilane compound, the ceria polymer composite particles may have a modification level of the aminosilane compound on the composite particles of at least about 5 percent (e.g., at least about 8 percent, at least about 10 percent, at least about 15 percent, or at least about 20 percent) to achieve the desired zeta potential. Moreover, the ceria polymer composite particles may have a modification level of less than or equal to about 50 percent (e.g., less than or equal to about 45 percent, or less than or equal to about 40 percent) to promote colloidal stability. Accordingly, the ceria polymer composite particles may have a modification level that is in a range from about 5 percent to about 50 percent (e.g., from about 5 percent to about 40 percent or from about 10 percent to about 40 percent). By modification level it is meant the percentage of the theoretical silanol groups on the polymer and/or hydroxyl groups on the protruding ceria particles that are covalently bonded with the amino silane compound. For the purposes of this disclosure, the theoretical amount of silanol/hydroxyl groups on the composite particles may be obtained by multiplying the total BET surface area of the composite particles by 7.35 per nm².

It will be appreciated that the condensation reaction between the silane group(s) in the modifying aminosilane compound and surface silanol group(s) on the polymer and/or the hydroxyl groups on the ceria particles may be a reversible equilibrium reaction, such that the actual modification level may not equal the theoretical modification level (a modification level calculated based on the amount of aminosilane added to the composition). Moreover the actual modification level in the polishing composition may depend upon the procedures used to formulate the composition. It will be appreciated that some procedures may strip or otherwise remove the aminosilane compound from the surface of the composite particles, thereby reducing the modification level.

In the disclosed embodiments, the actual modification level of the composite particles may be measured using the following procedure. The polishing composition is first passed through a mixed bed ion exchange column to remove unbound or loosely bound aminosilane from the composite particles. After ionic exchange, the total aminosilane concentration in the polishing composition (both bound and unbound) is determined by digesting the composition (including the composite particles) in concentrated nitric acid (or other strong acid) and evaluating the digested composition using proton NMR. The amount of unbound (e.g., dissolved) aminosilane in the polishing composition is determined by first removing the composite particles from the composition by ultra-centrifugation (e.g., at 40,000 rpm for 1 h) and then testing the decanted liquid layer using liquid chromatography mass spectrometry (LCMS) (for aminosilane concentrations in a range from about 1 to about 100 ppm) and/or NMR (for aminosilane concentrations in a range from about 100 to about 5000 ppm). The amount of bound (modifying) aminosilane is calculated as the difference between the measured total aminosilane and the measured unbound aminosilane. The modification level may then be calculated based upon the concentration of the composite particles in the polishing composition and the measured surface area thereof. For the purposes of this calculation the average number of surface silanol and/or hydroxyl groups on the composite particle is assumed to be 7.35 per nm².

It will be appreciated that covalently bonding the composite particles with the aminosilane compound may also increase the isoelectric point (IEP) thereof (as compared to untreated particles). In example embodiments the modification level is sufficient such that the IEP of the composite particles is at least about 5 (e.g., at least about 6). For the purposes of this disclosure the IEP is measured on the composite particles before the addition of other polishing composition compounds. The IEP is determined by titrating a sample using the electroacoustic method (e.g., via a Colloidal Dynamics Zetaprobe Analyzer®). The dispersion of the composite particles is diluted in deionized water to a solids (composite particle) concentration in a range from 0.2 to 1 weight percent. The diluted sample is titrated with 0.1N potassium hydroxide for a base titration (sample pH to 10.5). The zeta potential is measured using a Zetasizer® at least every 0.5 pH units during the titration. The IEP is identified by determining the pH value at which the zeta potential is 0 mV. The precise IEP value may be computed via interpolation between the pH values at which the zeta potential transitions from positive to negative.

The positive charge on the ceria polymer composite particles may alternatively or additionally be obtained by incorporating a positively charged monomer into the polymer matrix. For example, the polymer matrix may include a copolymer having first and second comonomers in which the first comonomer includes an acrylate silane or acrylamide silane group that is covalently bonded to the ceria particles and the second comonomer includes a positively charged nitrogen containing group. In such copolymer embodiments the second comonomer advantageously does not include a silicon atom.

In embodiments in which the second comonomer includes a nitrogen atom the second comonomer may include, for example, an amine group such as a primary amine, a secondary amine, a tertiary amine, or a quaternary amine group (such as a betaine group). Preferred embodiments include a quaternary amine group. In advantageous embodiments, the comonomer may include a quaternary amine group containing acrylate or methacrylate comonomer, such as 2-(N,N-dialkylamino)ethyl methacrylate, 3-[(3-acrylamidopropyl)dialkylamminio]propanoate, and/or 2-(methacryloyloxy)ethyl] dialkyl-(3-sulfopropyl)ammonium hydroxide.

The disclosed composite particles (anionic or cationic) may have substantially any suitable particle size. For the purposes of this disclosure, unless otherwise explicitly stated, the particle size of the treated composite particles is an equivalent circle diameter (ECD) particle size and is measured using electron microscopy images, such as TEM or SEM images, of a large number of particles (see Example 4).

In example embodiments, the ceria polymer composite particles may have an ECD particle size of about 20 nm or more (e.g., about 30 nm or more, about 40 nm or more, or about 50 nm or more). The ceria polymer composite particles may have an ECD particle size of about 300 nm or less (e.g., about 250 nm or less, about 200 nm or less, about 150 nm or less, or about 100 nm or less). Accordingly, the ceria polymer composite particles may have an ECD particle size in a range bounded by any two of the aforementioned endpoints, for example, from about 20 nm to about 300 nm (e.g., from about 30 nm to about 250 nm, from about 30 nm to about 200 nm, from about 40 nm to about 150 nm, from about 50 nm to about 150 nm, or from about 50 nm to about 100 nm).

In particularly advantageous embodiments, a ratio of the average ECD particle size of the discrete ceria particles to the average ECD particle size of the composite particles may greater than about 5% (e.g., greater than about 8% or greater than about 10%). The ratio may be less than about 30% (e.g., less than about 25% or less than about 20%. Accordingly, the ratio of the average ECD particle size of the discrete ceria particles to the average ECD particle size of the composite particles may be in a range bounded by any two of the aforementioned endpoints, for example, from about 5% to about 30% (e.g., from about 5% to about 25%, from about 8% to about 25%, from about 8% to about 25%, or from about 10% to about 20%). It will be understood that the average particle size of the discrete ceria particles and the average particle size of the composite particles used to compute the above ratios is obtained from TEM or SEM images and represent average sizes obtained over a large number of composite particles as described in Example 4.

The disclosed composite particles may also be characterized by an average number of discrete ceria particles per ceria polymer composite particle. In example embodiments, the average number may be determined from SEM images, for example, by manually counting the discrete ceria particles visible in the SEM images on the surface of the composite particles. The number obtained by manual counting may then be doubled to account for the back side of the imaged composite particles. In example embodiments, the average number of discrete ceria particles per ceria polymer composite particle may be greater than about 10 (e.g., greater than about 15, greater than about 20, or greater than about 25). The average number of discrete ceria particles per ceria polymer composite particle may be less than about 200 (e.g., less than about 150, less than about 125, less than about 100, or less than about 75). Accordingly, the average number of discrete ceria particles per ceria polymer composite particle may be in a range bounded by any two of the aforementioned endpoints, for example, from about 10 to about 200 (e.g., from about 15 to about 150, from about 15 to about 100, from about 20 to about 100, or from about 25 to about 75).

In certain example embodiments, the average number of discrete ceria particles per ceria polymer composite particle may alternatively be estimated via a three-dimensional model in which the composite particles are modeled as spheres having an average ECD particle size measured as described in Example 4. The discrete ceria particles are modeled as cuboctahedra in shape having ECD particle size as determined from SEM images of the composite particles. The discrete ceria particles are arranged around a polymer core with the ceria particles being embedded into the polymer to the midpoint of the ceria particles. A maximum spherical close-packing efficiency of 74% is used to account for gaps between randomly oriented octahedra at the surface. The total ceria volume per composite particle (based on the weight percents used in synthesis, theoretical densities for polymer and ceria, and the ECD particle sizes of the composite and ceria particles) is then divided by the average volume of a discrete ceria particles to obtain a modeled number of discrete ceria particles per ceria polymer composite particle (which may be within the same ranges recited above for manual counting).

As noted above, the measured particle size of a particle (such as the disclosed composite particles) commonly depends on the measurement technique used to make the measurement. As such, when the particle size of the composite particles is measured using dynamic light scattering, such as with a Malvern Zetasizer®, the composite particles may have an average particle size of about 20 nm or more (e.g., about 50 nm or more or about 80 nm or more). The composite particles may have an average particle size of about 500 nm or less (e.g., about 400 nm or less, about 300 nm or less, or about 200 nm or less). Accordingly, the composite particles may have an average particle size in a range bounded by any two of the aforementioned endpoints, for example, from about 20 nm to about 500 nm (e.g., from about 20 nm to about 400 nm, from about 50 nm to about 300 nm, or from about 80 nm to about 200 nm).

In example embodiments, the composite particles in the polishing composition are substantially all ceria polymer composite particles. In other words, the polishing composition does not include a significant amount of ceria particles or polymer particles other than the ceria particles and polymer matrix in the disclosed composite particles. By significant amount it is meant that less than about 1 percent (weight fraction) of the abrasive particles (e.g. less than about 0.5%) are ceria particles or polymer particles (non-composite particles).

In other example embodiments, the polishing composition does not include a significant amount of fine (very small) particles. By fine it is meant particles having a particle diameter in a range from about 5 nm to about 15 nm (whether ceria, polymer, or composite particles). By significant amount it is meant that less than about 1 percent (weight fraction) (e.g., less than about 0.5 percent or less than about 0.3 percent) of the abrasive particles are fine. The number of fine particles may be measured, for example, using differential mobility analysis (DMA).

The ceria polymer particles may have substantially any suitable theoretical inorganic to organic (ceria particle to polymer matrix) weight ratio. By “theoretical inorganic to organic weight ratio” it is meant the weight ratio of the ceria particles to the monomer prior to polymerization. As described in more detail below, the actual (or measured) inorganic to organic weight ratio of the composite particles after polymerization may be significantly more than the theoretical ratio. In example embodiments the theoretical inorganic to organic weight ratio is about lor greater (e.g., about 1.5 or greater, about 1.8 or greater or about 2 or greater). The theoretical inorganic to organic weight ratio may be about 5 or less (e.g., about 4 or less, about 3.5 or less, or about 3 or less). Accordingly, the ceria polymer composite particles may have a theoretical inorganic to organic weight ratio in a range bounded by any two of the aforementioned endpoints, for example, in a range from about 1 to about 5 (e.g., from about 1.5 to about 4 or from about 1.8 to about 3.5). In particularly advantageous embodiments, the treated composite particles may have a theoretical organic to inorganic weight ratio in a range from about 2 to about 3.

As noted above, the actual inorganic to organic weight ratio of the composite particles after polymerization may be significantly greater than the theoretical inorganic to organic weight ratio. While not wishing to be bound by theory, the difference between the actual and theoretical weight ratios may have many causes, for example, including alkoxide hydrolysis during polymerization, the presence of a silicon atom in the monomer, poorly emulsified polymerized organic material that is removed via filtration, and incomplete polymerization. Notwithstanding the foregoing, it will be appreciated that the actual inorganic to organic weight ratio may be estimated via thermal gravimetric analysis (TGA) mass loss measurements, for example, as described in more detail below in Example 4. The actual inorganic to organic weight ratio may be taken, for example, to be the percent mass remaining (the inorganics) divided by the percent mass loss (the organics). When estimated via TGA mass loss measurements, the actual (measured) inorganic to organic weight ratio of the composite particles may be about 3 or greater (e.g., about 4 or greater or about 5 or greater). Likewise, based on TGA mass loss measurements, the treated composite particles may have an actual organic to inorganic weight ratio of about 10 or less (e.g., about 8 or less or about 7 or less). Accordingly, the treated composite particles may have an actual organic to inorganic weight ratio in a range bounded by any two of the aforementioned endpoints, for example, in a range from about 3 to about 10 (e.g., from about 3 to about 8 or from about 4 to about 8). In particularly advantageous embodiments, the treated composite particles may have an actual organic to inorganic weight ratio in a range from about 5 to about 7.

The polishing composition may include substantially any suitable amount of the ceria polymer composite particles. For example, the polishing composition may include about 0.001 wt. % or more of the composite particles at point of use (e.g., about 0.01 wt. % or more, about 0.02 wt. % or more, about 0.05 wt. % or more, about 0.1 wt. % or more, or about 0.2 wt. % or more). The polishing composition may include about 5 wt. % or less of the composite particles at point of use (e.g., about 2 wt. % or less, about 1 wt. % or less, about 0.8 wt. % or less, or about 0.5 wt. % or less) Accordingly, it will be understood that the amount of ceria polymer composite particles may be in the polishing composition in a range bounded by any two of the aforementioned endpoints, for example, in a range from about 0.001 wt. % to about 2 wt. % at point of use (e.g., from about 0.01 wt. % to about 2 wt. %, from about 0.1 wt. % to about 1 wt. %, or from about 0.2 wt. % to about 1 wt. %).

A liquid carrier is generally used to facilitate the application of the ceria polymer composite particles and any optional chemical additives to the surface of the substrate to be polished. The liquid carrier may include any suitable carrier (e.g., a solvent) including lower alcohols (e.g., methanol, ethanol, etc.), ethers (e.g., dioxane, tetrahydrofuran, etc.), water, and mixtures thereof. Preferably, the liquid carrier comprises, consists essentially of, or consists of water, more preferably deionized water.

In embodiments that include anionic composite particles, the polishing composition is generally neutral or mildly alkaline, having a pH of greater than about 6 (e.g., greater than about 7). The polishing composition may have a pH of less than about 11 (e.g., less than about 10). Accordingly, the polishing composition may have a pH in a range bounded by any two of the aforementioned endpoints, for example in a range from about 6 to about 11 (e.g., from about 7 to about 10).

In embodiments that include cationic composite particles, the polishing composition is generally acidic having a pH of less than about 6 (e.g., less than about 5.5 or less than about 5). The polishing composition may have a pH of greater than about 2 (e.g., greater than about 2.5 or greater than about 3). Accordingly, the polishing composition may have a pH in a range bounded by any two of the aforementioned endpoints, for example, in a range from about 2 to about 6 (e.g., from about 2.5 to about 5.5 or from about 3 to about 5).

The pH of the polishing composition may be achieved and/or maintained by any suitable means. The polishing composition may include substantially any suitable pH adjusting agents or buffering systems. For example, suitable pH adjusting agents may include acetic acid, nitric acid, ammonium hydroxide, potassium hydroxide, triethanolamine, and the like while suitable buffering agents may include phosphates, sulfates, acetates, malonates, oxalates, borates, ammonium salts, and the like.

The disclosed polishing compositions may further optionally include substantially any suitable chemical mechanical polishing additives, for example, including a topography control agent, a silicon oxide polishing rate accelerator, a dispersant, and/or a biocide.

In example embodiments a topography control agent may include a cationic polymer. The cationic polymer may include substantially any suitable cationic polymer, for example, a cationic homopolymer, a cationic copolymer including at least one cationic monomer (and an optional nonionic monomer), and combinations thereof.

A cationic polymer may include substantially any suitable cationic homopolymer including cationic monomer repeat units, for example, including quaternary amine groups as repeat units. Suitable quaternary amine monomers include, for example, quaternized vinylimidazole (vinylimidazolium), methacryloyloxyethyltrimethylammonium (MADQUAT), diallyldimethylammonium (DADMA), methacrylamidopropyl trimethylammonium (MAPTA), quaternized dimethylaminoethyl methacrylate (DMAEMA), epichlorohydrin-dimethylamine (epi-DMA), cationic poly(vinyl alcohol) (PVOH), quaternized hydroxyethylcellulose, and combinations thereof. It will be appreciated that MADQUAT, DADMA, MAPTA, and DMAEMA commonly include a counter anion such as a carboxylate (e.g., acetate) or a halide anion (e.g., chloride). The disclosed embodiments are not limited in this regard.

The cationic polymer may also be a copolymer including at least one cationic monomer (e.g., as described in the preceding paragraph) and at least one nonionic monomer. Non-limiting examples of suitable nonionic monomers include vinylpyrrolidone, vinylcaprolactam, vinylimidazole, acrylamide, vinyl alcohol, polyvinyl formal, polyvinyl butyral, poly(vinyl phenyl ketone), vinylpyridine, polyacrolein, cellulose, hydroxylethyl cellulose, ethylene, propylene, styrene, and combinations thereof.

Example cationic polymers include but are not limited to poly(vinylimidazolium), poly(methacryloyloxyethyltrimethylammonium) (polyMADQUAT), poly(diallyldimethylammonium) (e.g., polyDADMAC) (i.e., Polyquatemium-6), poly(dimethylamine-co-epichlorohydrin), poly[bis(2-chloroethyl) ether-alt-1,3-bis[3-(dimethylamino)propyl]urea] (i.e., Polyquatemium-2), copolymers of hydroxyethyl cellulose and diallyldimethylammonium (i.e., Polyquatemium-4), copolymers of acrylamide and diallyldimethylammonium (i.e., Polyquatemium-7), quaternized hydroxyethylcellulose ethoxylate (i.e., Polyquatemium-10), copolymers of vinylpyrrolidone and quaternized dimethylaminoethyl methacrylate (i.e., Polyquatemium-11), copolymers of vinylpyrrolidone and quaternized vinylimidazole (i.e., Polyquatemium-16), Polyquatemium-24, a terpolymer of vinylcaprolactam, vinylpyrrolidone, and quaternized vinylimidazole (i.e., Polyquarternium-46), 3-Methyl-1-vinylimidazolium methyl sulfate-N-vinylpyrrolidone copolymer (i.e., Polyquatemium-44), and copolymers of vinylpyrrolidone and diallyldimethylammonium. Additionally, suitable cationic polymers include cationic polymers for personal care such as Luviquat® Supreme, Luviquat® Hold, Luviquat® UltraCare, Luviquat® FC 370, Luviquat® FC 550, Luviquat® FC 552, Luviquat® Excellence, GOHSEFIMER K210™, GOHSENX K-434, and combinations thereof.

The cationic polymer may also include an amino acid monomer (such compounds may also be referred to as polyamino acid compounds). Suitable polyamino acid compounds may include substantially any suitable amino acid monomer groups, for example, including polyarginine, polyhistidine, polyalanine, polyglycine, polytyrosine, polyproline, and polylysine. In certain embodiments, polylysine is a preferred polyamino acid. It will be understood that polylysine may include ε-polylysine and/or α-polylysine composed of D-lysine and/or L-lysine. The polylysine may thus include α-poly-L-lysine, α-poly-D-lysine, ε-poly-L-lysine, ε-poly-D-lysine, and mixtures thereof. In certain embodiments, the polylysine may be ε-poly-L-lysine. It will further be understood that the polyamino acid compound (or compounds) may be used in any accessible form, e.g., the conjugate acid or base and salt forms of the polyamino acid may be used instead of (or in addition to) the polyamino acid.

The cationic polymer may also (or alternatively) include a derivatized polyamino acid (i.e., a cationic polymer containing a derivatized amino acid monomer unit). For example, the derivatized polyamino acid may include derivatized polyarginine, derivatized polyornithine, derivatized polyhistidine, and derivatized polylysine. CMP compositions including derivatized polyamino acid compounds are disclosed in commonly assigned U.S. Pat. No. 11,492,514.

The polishing composition may include substantially any suitable amount of the cationic polymer. In general, the concentration is desirably high enough to provide adequate topography control, but low enough so that the polymer is soluble and so as not to reduce the polishing rates below acceptable levels. In example embodiments that include a cationic polymer, the concentration of the cationic polymer in the polishing composition may be in a range from about 0.1 ppm by weight to about 100 ppm by weight at point of use (e.g., from about 0.5 ppm to about 50 ppm, from about 2 ppm to about 20 ppm, or from about 2 ppm to about 10 ppm).

In example embodiments a polishing rate accelerator may include a nitrogen containing organic acid such as a suitable hydroxamic acid compound or a nitrogen-containing heterocyclic acid compound. Example rate enhancers may include, for example, picolinic acid, nicotinic acid, quinaldic acid, iso-nicotinic acid, quinolinic acid, benzhydroxamic acid, salicylhydroxamic acid, and mixtures thereof.

The polishing composition may include substantially any suitable amount of polishing rate accelerator. In general, the concentration is desirably high enough to provide sufficient rate enhancement, but low enough to not cause other undesirable polishing effects. In example embodiments that include a nitrogen containing organic acid, the concentration of the nitrogen containing organic acid in the polishing composition may be in a range from about 10 ppm by weight to about 2 weight percent (20,000 ppm) at point of use (e.g., from about 10 ppm to about 10,000 ppm, from about 20 ppm to about 5000 ppm, from about 20 ppm to about 2000 ppm, from about 30 ppm to about 1000 ppm, or from about 50 ppm to about 1000 ppm).

The polishing composition may optionally further include a biocide. The biocide may include any suitable biocide, for example an isothiazolinone biocide. The amount of biocide in the polishing composition typically is in a range from about 1 ppm to about 50 ppm by weight at point of use or in a concentrate, and preferably from about 1 ppm to about 20 ppm.

In the disclosed embodiments, ceria polymer composite particles may be formed, for example, by preparing an emulsion of negatively charged ceria particles and a silane monomer in an aqueous based carrier. The emulsion may be polymerized (e.g., via heating and adding an initiator to the emulsion) to obtain a dispersion of ceria polymer composite particles in which the ceria polymer composite particles include ceria particles covalently bonded to and at least partially embedded in a polymer matrix. In example embodiments, an aminosilane compound may be admixed with the dispersion of ceria polymer composite particles and the admixture heated to covalently bond the aminosilane compound to an outer surface of the ceria polymer composite particles (e.g., to the polymer matrix and/or the ceria particles) to obtain a dispersion of positively charged ceria polymer composite particles.

The polishing composition may then be prepared using any suitable techniques, many of which are known to those skilled in the art. For example, the polishing composition components (such as the cationic polymer, the nitrogen containing organic acid, and/or the biocide) may mixed together with an appropriate amount of water. A dispersion of the ceria polymer composite particles may then be added to and blended with the mixture. Substantially any suitable blending techniques may be used for achieving adequate mixing. Such blending/mixing techniques are well known to those of ordinary skill in the art.

The polishing composition may advantageously be supplied as a one-package system comprising the ceria polymer composite particles having the above described physical properties and the other optional components. However, the disclosed embodiments are not limited in this regard as various other two-container, or three- or more-container, combinations of the components of the polishing composition are within the knowledge of one of ordinary skill in the art. For example, the ceria polymer composite particles may be provided in a first container and one or more of the optional additives may be provided in a second container.

The polishing composition of the invention may also be provided as a concentrate which is intended to be diluted with an appropriate amount of water prior to use. In such concentrated embodiments, the polishing composition concentrate may include the ceria polymer composite particles, water, and other optional components such as a cationic polymer and/or a nitrogen containing organic acid, and a biocide in amounts such that upon dilution of the concentrate with an appropriate amount of water each component of the polishing composition will be present in the polishing composition in an amount within the appropriate ranges recited above for each component. For example, the composite particles and other optional components may each be present in the polishing composition in an amount that is about 2 times (e.g., about 3 times, about 4 times, about 5 times, or even about 10 times) greater than the point of use concentrations recited above for each component so that, when the concentrate is diluted with an equal volume of (e.g., 2 equal volumes of water, 3 equal volumes of water, 4 equal volumes of water, or even 9 equal volumes of water respectively) each component will be present in the polishing composition in an amount within the ranges set forth above for each component. Furthermore, as will be understood by those of ordinary skill in the art, the concentrate may contain an appropriate fraction of the water present in the final polishing composition in order to ensure that other components are at least partially or fully dissolved in the concentrate.

The disclosed polishing compositions may be used to polish substantially any substrate, for example, including a dielectric layer such as a silicon oxide layer. Certain advantageous embodiments may be particularly useful in the polishing a dielectric layer at high removal rates and low defectivity levels (e.g., low scratch counts and low surface roughness). The dielectric layer may be a metal oxide such as a silicon oxide layer derived from tetraethylorthosilicate (TEOS), porous metal oxide, porous or non-porous carbon doped silicon oxide, fluorine-doped silicon oxide, glass, organic polymer, fluorinated organic polymer, or any other suitable high or low-k insulating layer.

The polishing method of the invention is particularly suited for use in conjunction with a chemical mechanical polishing (CMP) apparatus. Typically, the apparatus includes a platen, which, when in use, is in motion and has a velocity that results from orbital, linear, or circular motion, a polishing pad in contact with the platen and moving with the platen when in motion, and a carrier that holds a substrate to be polished by contacting and moving relative to the surface of the polishing pad. The polishing of the substrate takes place by the substrate being placed in contact with the polishing pad and the polishing composition of the invention and then the polishing pad moving relative to the substrate, so as to abrade at least a portion of the substrate (such as a dielectric material as described herein) to polish the substrate.

A substrate may be planarized or polished with the chemical mechanical polishing composition with any suitable polishing pad (e.g., polishing surface). Suitable polishing pads include, for example, woven and non-woven polishing pads. Moreover, suitable polishing pads can comprise any suitable polymer of varying density, hardness, thickness, compressibility, ability to rebound upon compression, and compression modulus. Suitable polymers include, for example, polyvinylchloride, polyvinylfluoride, nylon, fluorocarbon, polycarbonate, polyester, polyacrylate, polyether, polyethylene, polyamide, polyurethane, polystyrene, polypropylene, co-formed products thereof, and mixtures thereof.

The following examples further illustrate the invention but, of course, should not be construed as in any way limiting its scope.

### Example 1

Dispersions of ceria polymer composite particles were prepared using two distinct ceria particle dispersions (characterized in Table 1A). Citrate stabilized ceria dispersions were prepared by admixing the ceria dispersion with deionized water and a 1 weight percent solution of citric acid monohydrate to obtain dispersions having 8 weight percent of the ceria particles. The pH was adjusted to 10 using 10% KOH. The resulting citrate stabilized ceria dispersions were sonicated to break up any resulting agglomerates and had conductivities of 1039 μS/cm (1A) and 3245 μS/cm (1B).

A sample of each citrate stabilized ceria dispersion prepared above was admixed with 3-trimethoxysilylpropyl methacrylate (the monomer) at a predetermined MPS to ceria weight ratio (see Table 1A). The mixture was stirred at 350 rpm and the pH was maintained in a range from 9.5 to 10 by slow addition of 10% KOH (as necessary). The stirring rate was then reduced to 150 rpm and the mixture was heated to 50 degrees C. for two hours with the reactor open to air before purging with nitrogen for another 30 minutes.

An initiator mixture including azobisisobutyronitrile (AIBN) in ethanol was nitrogen purged and then added to the reactor. The temperature was increased to 75 degrees C. After 5 hours the resulting product was cooled with stirring and filtered through a 0.5 micron bag filter. The filtered dispersion was then passed through a mixed bed ion exchange column.

The particle sizes of the resulting ceria polymer composite particles were measured using a Zetasizer® (Malvern Instruments). Table 1B lists the percent solids, pH, conductivity and Malvern particle size for each of the prepared compositions.

TABLE 1A

| Composite | Ceria ECD | Ceria BET | MPS to |
|---|---|---|---|
| Ceria Polymer | Particle Size | Surface Area | Ceria Ratio |
| Composition | (nm) | (m²/g) | (wt. %) |
| 1A | 35 | 32 | 0.36 |
| 1B | 11 | 79 | 0.42 |

TABLE 1B

| Composite | Mass | | | Malvern |
|---|---|---|---|---|
| Ceria Polymer | Solids | | Conductivity | Particle Size |
| Composition | (%) | pH | (μS/cm) | (nm) |
| 1A | 6.3 | 9.0 | 212 | 320 |
| 1B | 2.0 | 9.2 | 45 | 103 |

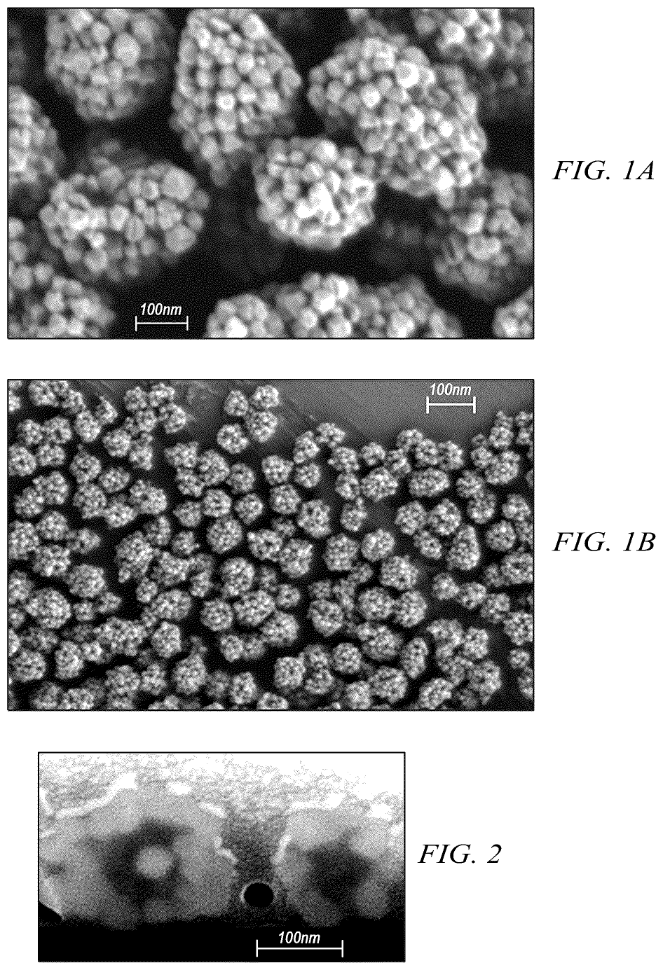

FIGS. 1A and 1B depict SEM micrographs of example ceria polymer composite particles obtained from dispersions 1A and 1B. Note that the ceria polymer composite particles include discrete ceria particles (light) embedded in a polymer matrix (dark).

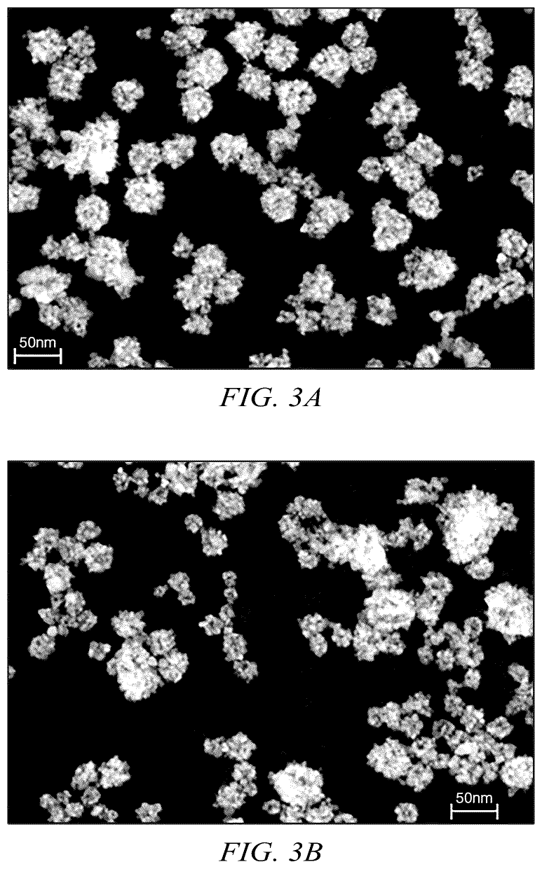

FIG. 2 depicts an SEM image obtained using focused ion beam scanning electron microscopy (FIB-SEM) tomography on composite particles obtained from composition 1A. The composite particles were coated with platinum and milled using FIB to their approximate midpoint prior to obtaining the SEM images.

### Example 2

Dispersions of cationic ceria composite particles were prepared by modifying compositions 1A and 1B (prepared in Example 1) with an aminosilane compound (these cationic dispersions are referred to herein below as compositions 2A and 2B). A solution of 1 weight percent APTMS was added to each dispersion with stirring to achieve target (theoretical) modification levels of 30 percent for composition 2A and 20 percent for composition 2B. The pH was adjusted to 10 using KOH. The reaction vessel was heated to 75 degrees C. with stirring and held for 20 hours. The reaction product was allowed to slowly cool to room temperature and was then passed through a cationic ion exchange column.

The particle sizes of the resulting modified ceria polymer composite particles were measured using a Zetasizer® (Malvern Instruments). Table 2 lists the percent solids, pH, conductivity and Malvern particle size for each of the prepared compositions.

TABLE 2

| Composite | Mass | | | Malvern |
|---|---|---|---|---|
| Ceria Polymer | Solids | | Conductivity | Particle Size |
| Composition | (%) | pH | (μS/cm) | (nm) |
| 2A | 4.8 | 3.8 | 96 | 311 |
| 2B | 1.9 | 3.6 | 97 | 117 |

### Example 3

The Smoluchowski zeta potential and IEP of the ceria polymer composite particle compositions prepared in Examples 1 and 2 were evaluated. The zeta potential (ZP) values were measured using the Zetaprobe Analyzer® available from Colloidal Dynamics (with the Smoluchowski zeta potential being selected in the tool software settings) at the pH values shown in Table 3. The IEP was also estimated using the procedure described above and is listed in the Table.

TABLE 3

| | Composition | Composition | Composition | Composition |
|---|---|---|---|---|
| pH | 1A | 1B | 2A | 2B |
| 2 | 17 | | 51 | |
| 3 | 3 | 23 | 58 | |
| 4 | −24 | 8 | 35 | |
| 5 | −46 | −22 | 10 | 31 |
| 6 | −56 | −38 | −6 | 19 |
| 7 | −60 | −44 | −28 | −8 |
| 8 | −62 | −50 | −43 | −17 |
| IEP | 3.1 | 4.3 | 5.6 | 6.7 |

As is readily apparent from the data set forth in Table 3, the compositions 2A and 2B including the aminosilane modified composite particles have higher IEP values than compositions 1A and 1B.

### Example 4

The ECD particle size and thermogravimetric analysis (TGA) mass loss of the modified composite particles in compositions 2A and 2B were evaluated. The ECD particle size was measured using secondary electron SEM images of oven dried particles. The ECD particle size was calculated from the SEM images by first segmenting the images to identify the treated composite particles in the image. The segmenting algorithm extracted particle boundaries using a supervised machine learning pixel classifier model. Such algorithms are well known in image processing. A two-dimensional area was extracted from the binarized particle segments. The equivalent circle diameter ECD of each of the particles was then computed from the corresponding extracted areas using the well know circle area equation A=π(D/2)², with the d being computed from the average of the individual particles. A watershed was applied to the segment prior to analysis using an appropriate tolerance to separate particles in contact. The SEM images were further evaluated to manually count an average number of discrete ceria particles per composite particle.

Thermogravimetric analysis (TGA) mass loss of compositions 2A and 2B was evaluated. A sample of each of the compositions was oven dried overnight at 60 degrees C. to obtain corresponding samples of dry particles. For a hypothetical polishing composition the composition may be purified first via dialysis or multiple centrifugation and rinsing cycles before being oven dried as described above. The dried particles were then ground using a mortar and pestle. TGA curves (normalized mass loss versus temperature) were generated using a TGA Q500 instrument with an auto sampler. Nitrogen gas was used at a flow rate of 40 ml/min. The temperature was ramped at 10 degrees C. per minute from room temperature to 800 degrees C. at a rate of 10 degrees C. per minute.

The normalized mass of the composite particle samples was found to level off at temperatures above about 550 degrees C. Percent mass loss values were obtained by subtracting the normalized mass at 600 degrees C. from the normalized mass at 200 degrees C. (i.e., by subtracting the total remaining mass at 600 degrees C. from the total mass at 200 degrees C. and then dividing the result by the total mass at 200 degrees C.). Table 4 lists the ECD particle size, number of ceria particles per composite particle, the percent mass loss, and a computed inorganic to organic ratio based on the TGA mass loss.

TABLE 4

| Composite | ECD Particle | Ceria Particles | TGA Mass | Inorganic |
|---|---|---|---|---|
| Ceria Polymer | Size | per Composite | Loss | to Organic |
| Composition | (nm) | Particle | (%) | Ratio |
| 2A | 206 | 46 | 13.0 | 6.7 |
| 2B | 62 | 32 | 15.4 | 5.5 |

### Example 5

Six polishing compositions were prepared. Compositions 5A and 5B were control compositions and included 0.1 weight percent and 0.2 weight percent of the 11 nm ceria particles that were used in the synthesis of the ceria polymer composite particles in compositions 1B and 2B. Compositions 5C, 5D, and 5E included 0.1 weight percent (5C) or 0.2 weight percent (5D and 5E) of the cationic (aminosilane modified) ceria polymer composite particles synthesized in composition 2B. Composition 5E further included 300 ppm picolinic acid. The pH of each composition was adjusted to 4 using either acetic acid or triethanolamine.

Table 5A gives conductivity, average particle size, and zeta potential values for each of compositions 5C, 5D, and 5E. The particle size values and zeta potential were measured using the Malvern Zetasizer®.

TABLE 5A

| Polishing | Conductivity | Particle Size | Zeta Potential |
|---|---|---|---|
| Composition | (μS/cm) | (nm) | (mV) |
| 5C | 45 | 141 | 43 |
| 5D | 42 | 118 | 48 |
| 5E | 48 | 119 | 48 |

The CMP performance of polishing compositions 5A-5E was evaluated using a Mirra® CMP polishing tool (Applied Materials) with an E6088 polishing pad (Entegris) and in-situ conditioning using a Saesol DS8051 conditioner at 6 lbs. Blanket TEOS and LP-SiN were obtained by polishing 200 mm blanket wafers at a downforce of 3.0 psi, a platen speed of 100 rpm, a head speed of 85 rpm, and a slurry flow rate was 150 mL/min. Pattern removal rates are shown for 900×900 μm line features. Surface roughness values (Ra) were computed from atomic force microscope (AFM) images obtained from the TEOS surfaces polished using compositions 5C, 5D, and 5E. Removal rates and surface roughness values are shown in Table 5B.

TABLE 5B

| | TEOS | LP-SiN | | Patterned | Ra Surface |
|---|---|---|---|---|---|
| Polishing | RR | RR | | RR | Roughness |
| Composition | (Å/min) | (Å/min) | TEOS:SiN | (Å/min) | (Å) |
| 5A | 23 | 6 | 4 | | |
| 5B | 7 | 6 | 1 | 5 | |
| 5C | 1840 | 8 | 230 | | 1.3 |
| 5D | 2023 | 7 | 289 | 284 | 1.3 |
| 5E | 1660 | 6 | 277 | 1430 | 1.2 |

As is readily apparent from the data set forth in Table 5B, polishing compositions 5C, 5D, and 5E including the inventive ceria polymer composite particles achieved high TEOS removal rates and high TEOS to SiN selectivities. Polishing composition 5E further including picolinic acid also achieved a high patterned TEOS removal rate. Moreover, each of the inventive compositions further produced very smooth TEOS surfaces having Ra surface roughness values less than 1.5 Å.

### Example 6

Three polishing compositions were prepared. Compositions 6A and 6B included 0.2 weight percent of the anionic ceria polymer composite particles synthesized in composition 1B. The compositions were adjusted to pH values of 7 (6A) or 9 (6B) using either acetic acid or triethanolamine. Composition 6C included 0.3 weight percent of the anionic ceria polymer composite particles synthesized in composition 1A and 250 ppm picolinic acid. The pH was 8.5.

Table 6A gives conductivity, average particle size, and zeta potential values for each of compositions 6A and 6B. The particle size and zeta potential values were measured using the Malvern Zetasizer® except for 6C, which was measured using a Horiba LA-960 Instrument and DT1202 from Dispersion Technology, Inc. with a Smoluchowski approximation.

TABLE 6A

| Polishing | Conductivity | Particle Size | Zeta Potential |
|---|---|---|---|
| Composition | (μS/cm) | (nm) | (mV) |
| 6A | 12 | 98 | −29 |
| 6B | 18 | 101 | −43 |
| 6C | 220 | 291 | −36 |

The CMP performance of polishing compositions 6A-6C was evaluated using a Mirra® CMP polishing tool (Applied Materials) with an E6088 polishing pad (Entegris) and in-situ conditioning using a Saesol DS8051 conditioner at 6 lbs. Blanket TEOS and LP-SiN were obtained by polishing 200 mm blanket wafers at a downforce of 3.0 psi, a platen speed of 100 rpm, a head speed of 85 rpm, and a slurry flow rate was 150 ml/min. Surface roughness values (Ra) were computed from atomic force microscope (AFM) images obtained from the TEOS surfaces polished using compositions 6A and 6B. Removal rates and surface roughness values are shown in Table 6B.

TABLE 6B

| | | | | Ra Surface |
|---|---|---|---|---|
| Polishing | TEOS RR | LP-SiN RR | | Roughness |
| Composition | (Å/min) | (Å/min) | TEOS:SiN | (Å) |
| 6A | 397 | 54 | 7 | 1.3 |
| 6B | 90 | 117 | 0.8 | 1.2 |
| 6C | 1789 | 206 | 9 | |

As is readily apparent from the data set forth in Table 6B, polishing composition 6C including the inventive ceria polymer composite particles and picolinic acid achieved high TEOS removal rates. Polishing composition 6B advantageously achieved similar TEOS and SiN removal rates (approximately a 1:1 selectivity). Moreover, inventive compositions 6A and 6B further produced very smooth TEOS surfaces having Ra surface roughness values less than 1.5 Å.

### Example 7

Another dispersion of ceria polymer composite particles was prepared using a dispersion of small ceria particles (having a BET surface area of 120 m²/g and an estimated ECD particle size of 7 nm). A citrate stabilized ceria dispersion was prepared (as described above in Example 1) having 4.9 weight percent of the ceria particles, a pH of 9.6, and a conductivity of 329 μS/cm. The citrate stabilized ceria dispersion was admixed with 3-trimethoxysilylpropyl methacrylate (the monomer) at an MPS to ceria weight ratio of 0.64. The mixture was polymerized following the procedure of Example 1 to obtain a dispersion of ceria polymer composite particles (composition 7A).

A dispersion of cationic ceria polymer composite particles (composition 7B) was prepared by modifying a sample of composition 7A with an aminosilane compound (APTMS) using the procedure described in Example 2. The cationic composite particles had a target (theoretical) modification level of 20 percent.

The particle sizes of the resulting ceria polymer composite particles were measured for each composition using a Zetasizer® (Malvern Instruments). ECD particle sizes were also measured for each composition using the procedure described in Example 4. Table 7B lists the percent solids, pH, conductivity, the Malvern particle size, and the ECD particles size for each composition. FIGS. 3A and 3B depict SEM micrographs of example ceria polymer composite particles obtained from dispersions 7A and 7B.

TABLE 7A

| Composite | Mass | | | Malvern | ECD |
|---|---|---|---|---|---|
| Ceria Polymer | Solids | | Conductivity | Particle Size | Particle Size |
| Composition | (%) | pH | (μS/cm) | (nm) | (nm) |
| 7A | 2.0 | 8.2 | 31 | 64 | 27 |
| 7B | 1.9 | 3.5 | 93 | 96 | 25 |

The Smoluchowski zeta potential and IEP of ceria polymer composite particle compositions 7A and 7B were evaluated using the same technique described in Example 3 and are listed in Table 7B.

TABLE 7B

| pH | Composition 7A | Composition 7B |
|---|---|---|
| 3 | −6 | 43 |
| 4 | −26 | 35 |
| 5 | −39 | 20 |
| 6 | −46 | 5 |
| 7 | −49 | −9 |
| 8 | | −24 |
| IEP | 2.6 | 6.3 |

### Example 8

Two polishing compositions were prepared. Composition 8A was a control composition that included 0.29 weight percent of the small ceria particles that were used in the synthesis of the ceria polymer composite particles in compositions 7A and 7B. Composition 8B included 0.29 weight percent of the cationic (aminosilane modified) ceria polymer composite particles in composition 7B. The pH of each polishing composition was adjusted to 4 using either acetic acid or triethanolamine.

Table 8A lists the conductivity, average particle size, and zeta potential values for each of compositions 8A and 8B. The particle size and zeta potential values were measured using the Malvern Zetasizer®.

TABLE 6A

| Polishing | Conductivity | Particle Size | Zeta Potential |
|---|---|---|---|
| Composition | (μS/cm) | (nm) | (mV) |
| 8A | 67 | 50 | 56 |
| 8B | 43 | 87 | 42 |

The CMP performance of polishing compositions 8A and 8B was evaluated using a Mirra® CMP polishing tool (Applied Materials) with an E6088 polishing pad (Entegris) using the same polishing recipe used in Examples 5 and 6. Blanket TEOS and LP-SiN were polished. The polishing data is given in Table 8B.

TABLE 8B

| Polishing | TEOS RR | LP-SiN RR | |
|---|---|---|---|
| Composition | (Å/min) | (Å/min) | TEOS:SiN |
| 8A | 195 | 12 | 16 |
| 8B | 1561 | 11 | 142 |

As is readily apparent from the data set forth in Table 8B, polishing composition 8B including the inventive ceria polymer composite particles achieved higher TEOS removal rates and high TEOS to SiN selectivities.

It will be understood that the recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the invention and does not pose a limitation on the scope of the invention unless otherwise claimed. No language in the specification should be construed as indicating any non-claimed element as essential to the practice of the invention.

Preferred embodiments of this invention are described herein, including the best mode known to the inventors for carrying out the invention. Variations of those preferred embodiments may become apparent to those of ordinary skill in the art upon reading the foregoing description. The inventors expect skilled artisans to employ such variations as appropriate, and the inventors intend for the invention to be practiced otherwise than as specifically described herein. Accordingly, this invention includes all modifications and equivalents of the subject matter recited in the claims appended hereto as permitted by applicable law. Moreover, any combination of the above-described elements in all possible variations thereof is encompassed by the invention unless otherwise indicated herein or otherwise clearly contradicted by context.

1. A chemical mechanical polishing composition comprising:
a liquid carrier; and
ceria polymer composite particles dispersed in the liquid carrier, wherein the ceria polymer composite particles comprise ceria particles covalently bonded to and at least partially embedded in a polymer matrix.

2. The composition of claim 1, wherein the polymer matrix comprises a silicon containing polymer that is covalently bonded to the ceria particles.

3. The composition of claim 2, wherein the ceria polymer composite particles comprise Ce—O—Si covalent bonds between the ceria particles and the polymer matrix.

4. The composition of claim 1, wherein a ratio of an average ECD particles size of the ceria particles to an average ECD particle size of the ceria composite particles is in a range from about 5% to about 30%.

5. The composition of claim 1, wherein:
the composition has a pH of greater than about 6; and
the ceria polymer composite particles have a Smoluchowski zeta potential of less than about negative 25 mV in the polishing composition as measured using an electroacoustic analyzer.

6. The composition of claim 1, further comprising:
an aminosilane compound that is covalently bonded with an outer surface of the ceria polymer composite particles such that the ceria polymer composite particles have a positive charge in the polishing composition.

7. The composition of claim 6, wherein:
the composition has a pH of less than about 5; and
the ceria polymer composite particles have a Smoluchowski zeta potential of greater than about 30 mV in the polishing composition as measured using an electroacoustic analyzer.

8. The composition of claim 6, wherein the ceria polymer composite particles have a modification level of the aminosilane compound of at least about 10 percent.

9. The composition of claim 1, wherein the polymer matrix comprises an acrylate or a methacrylate polymer.

10. The composition of claim 1, wherein the ceria particles have an average ECD particle size in a range from about 2 nm to about 40 nm.

11. The composition of claim 1, wherein the ceria particles have a BET surface area in a range from about 20 m²/g to about 300 m²/g.

12. The composition of claim 1, wherein the ceria polymer composite particles have a theoretical inorganic to organic weight ratio in a range from about 1.5 to about 4 or an actual inorganic to organic weight ratio in a range from about 4 to about 8 as determined by thermal gravimetric analysis weight loss measurements.

13. The composition of claim 1, wherein the ceria polymer composite particles have an equivalent circle diameter average particle size in a range from about 20 nm to about 300 nm.

14. The composition of claim 1, wherein a ratio of an average ECD particle size of the ceria particles to an average ECD particle size of the composite particles is in a range from about 5% to about 30%.

15. The composition of claim 1, comprising from about 0.01 weight percent to about 2 weight percent of the ceria polymer composite particles at point of use.

16. The composition of claim 1, further comprising a nitrogen containing organic acid or a cationic polymer.

17. A method for synthesizing a dispersion of ceria polymer composite particles, the method comprising:
preparing an emulsion of negatively charged ceria particles and a silane monomer;
polymerizing the emulsion to obtain the dispersion of ceria polymer composite particles, wherein the ceria polymer composite particles comprise ceria particles covalently bonded to and at least partially embedded in a polymer matrix.

18. The method of claim 17, further comprising:
covalently bonding an aminosilane compound to the ceria polymer composite particles to obtain a dispersion of positively charged ceria polymer composite particles.

19. A method of chemical mechanical polishing a substrate, the method comprising:
contacting the substrate with a polishing composition include a liquid carrier and ceria polymer composite particles dispersed in the liquid carrier, wherein the ceria polymer composite particles comprise ceria particles covalently bonded to and at least partially embedded in a polymer matrix;
moving the polishing composition relative to the substrate; and
abrading the substrate to remove at least a portion of a dielectric material from the substrate and thereby polish the substrate.

20. The method of claim 19, wherein the polishing composition further includes an aminosilane compound that is covalently bonded with an outer surface of the ceria polymer composite particles such that the ceria polymer composite particles have a positive charge in the polishing composition and wherein the polishing composition has a pH of less than 5.
